(19) United States
(12) Patent Application Publication
(10) Pub. No.: US 2020/0369514 A1
(43) Pub. Date: Nov. 26, 2020

(54) PACKAGING FOR A MEMS TRANSDUCER

(71) Applicant: Cirrus Logic International Semiconductor Ltd., Edinburgh (GB)

(72) Inventors: Roberto BRIOSCHI, Austin, TX (US); Rkia ACHEHBOUNE, Edinburgh (GB); David PATTEN, Austin, TX (US)

(73) Assignee: Cirrus Logic International Semiconductor Ltd., Edinburgh (GB)

(21) Appl. No.: 16/874,162

(22) Filed: May 14, 2020

Related U.S. Application Data
(60) Provisional application No. 62/851,220, filed on May 22, 2019.

(30) Foreign Application Priority Data
Jun. 17, 2019 (GB) 1908640.4

(51) Int. Cl. B81B 7/00; B81B 3/00; H04R 1/04

(52) U.S. Cl. CPC B81B 7/007; B81B 3/0064; B81B 7/0006; H04R 1/04; H04R 2201/003; B81B 2207/012; B81B 2207/07; B81B 2207/095; B81B 2201/0257

(57) ABSTRACT

The application describes a moulded interposer member for a MEMS transducer package. The interposer member comprises a void region and at least one through hole or channel.

### TECHNICAL FIELD

This application relates to packaging and packaging elements for a micro-electro-mechanical system (MEMS) device and to processes for fabricating such packaging and packaging elements. In particular, this application relates to packaging and packaging elements for a MEMS capacitive microphone device.

### BACKGROUND

MEMS devices are becoming increasingly popular. MEMS transducers, and especially MEMS capacitive microphones, are increasingly being used in electronic devices and systems and especially portable electronic devices such as mobile telephones, headphones and other portable devices.

Microphone devices formed using MEMS fabrication processes typically comprise one or more moveable membranes and a static backplate, with a respective electrode deposited on the membrane(s) and backplate, wherein one electrode is used for read-out/drive and the other is used for biasing. A substrate supports at least the membrane(s) and typically the backplate also. In the case of MEMS pressure sensors and microphones the read out is usually accomplished by measuring the capacitance between the membrane and backplate electrodes. In the case of transducers, the device is biased by a potential difference provided across the membrane and backplate electrodes.

A MEMS transducer will typically be housed within a package which allows easy handling and assembly and serves to protect the primary substrate and the component supported thereby from e.g. mechanical damage, RF noise and environmental contamination. The package also provides a means—e.g. an external conductive contact—for connecting the package to a circuit board or other elements.

A package which houses a microphone transducer will typically have a sound port to allow transmission of sound waves to/from the transducer within the package. The transducer may be configured so that the flexible membrane is located between first and second volumes, i.e. spaces/cavities that may be filled with air (or some other gas suitable for transmission of acoustic waves), and which are sized sufficiently so that the transducer provides the desired acoustic response. The sound port acoustically couples to a first volume on one side of the transducer membrane, which may sometimes be referred to as a front volume. The second volume, sometimes referred to as a back volume, on the other side of the one of more membranes is generally required to allow the membrane to move freely in response to incident sound or pressure waves, and this back volume may be substantially sealed (although it will be appreciated by one skilled in the art that for MEMS microphones and the like the first and second volumes may be connected by one or more flow paths, such as small holes in the membrane, that are configured so as present a relatively high acoustic impedance at the desired acoustic frequencies but which allow for low-frequency pressure equalisation between the two volumes to account for pressure differentials due to temperature changes or the like.)

Various packaging configurations are known. For example, a package for a MEMS transducer typically comprises a package substrate, which may be formed of a printed circuit board (PCB), and a cover portion which extends in a plane overlying the upper surface of the package substrate supported by side walls. According to some arrangements the cover portion and the side walls may be formed of two further PCBs. The three PCBs are bonded together wherein the middle PCB—or interposer member—comprises an opening which defines the chamber of the package. This arrangement is sometimes referred to as a “three-piece package”.

The MEMS transducer is attached to the upper surface of the package substrate within the chamber. The package may also comprise an integrated circuit (IC) which may be formed on a discrete die of semiconductor material or may be formed on the same die as the transducer. The integrated circuit will be customised for a particular application. The integrated circuit will be connected to electrodes of the transducer 101 such that an electrically conductive path is provided between the integrated circuit and an electrical connection provided on an external surface of the package. The integrated circuit typically provides bias to the transducer and buffers or amplifies a signal from the transducer. It will be appreciated that the package needs to facilitate an electrical connection between one or more planes of the package, e.g. between a first plane of the IC and a second plane of an external contact. This is typically achieved by one or more conductive vias which extend through the package elements including the side walls of the package.

According to previously proposed arrangements which utilise an interposer member or portion (e.g. a PCB) between a cover portion and a supporting substrate portion, it will be appreciated that the interposer member needs to be processed to define the interior chamber of the package. This typically involves milling or punching the interposer member to remove the material of the interposer member. The interposer also needs to define electrical through vias which pass through the side walls of the package. These electrical through vias are typically created by firstly drilling individual through holes through the interposer and then electroplating the through holes to create the electrical through vias. A number of problems and/or disadvantages are potentially associated with the speed and accuracy of milling and/or punching material from the interposer portion of a package.

### SUMMARY

The present aspects seek to provide an interposer member or structure which alleviates the problems associated with previously proposed arrangements.

According to at least one example of a first aspect there is provided an interposer member for a MEMS package, wherein the interposer member is formed of a mould material and comprises: a void which extends through the interposer member from an upper surface to a lower surface of the interposer member; one or more through holes which extend between the upper surface of the interposer member and the lower surface of the interposer member. The one or more through holes may be plated with or comprise with an electrically conductive material. A plurality of through holes may be provided, wherein at least some of the through holes are spaced on a notional path which surrounds the void.

According to at least one example of a second aspect there is provided a lid structure for a MEMS package, the lid comprising an interposer member according to an example of the first aspect formed in rigid, mechanical/electrical connection with a first surface of a cover member. Thus, the interposer member defines at least one side wall of the lid structure. The cover member may comprise at least one electrical contact formed on a second surface of the cover member, the second surface being opposite to the first surface. The cover member may comprise at least one through hole which extends through the plane of the cover member between the first surface and the second surface thereof.

According to at least one example of a third aspect there is provided a MEMS package comprising a lid structure according to an example of the second aspect and further comprising a supporting substrate for supporting the lid structure. The lid structure may be attached to a first (upper) surface of the supporting substrate by one or more solder bonds. The supporting substrate comprises at least one electrical contact formed on an upper surface thereof, wherein a via of the interposer member corresponds to each electrical contact and is provided so as to at least partially overlies the corresponding electrical contact. A ring of conductive material may be formed on an upper surface of the supporting substrate, the ring of conductive material underlying at least some of the plurality of vias of the interposer member. The supporting substrate may comprises a cavity which extends through the plane of the package substrate and defines an acoustic port of the package.

According to at least one example a MEMS microphone transducer is provided on the upper surface of the supporting substrate. The MEMS microphone transducer may comprise a flexible membrane which deflects in response to a pressure differential across the membrane, and wherein the MEMS microphone transducer is provided such that the flexible membrane overlies the acoustic port of the package. An IC may be mounted to the upper surface of the supporting substrate.

According to at least one example the supporting substrate may comprise a moulded substrate. The moulded substrate may comprises a port hole die which defines an acoustic port of the package and an IC die, wherein the port hole die and the IC die are held in fixed positional relationship relative to each other by means of a moulded frame structure. The port hole die and/or the IC die can be considered to be formed within the plane of the substrate such that they are substantially flush with one or both of the upper and lower planar surfaces of the moulded substrate.

According to at least one example of a further aspect there is provide a substrate structure for a MEMS transducer package comprising an interposer member according to an example of a previous aspect and a moulded substrate, wherein the interposer member is mounted on, or formed integrally with, the moulded substrate and wherein the interposer member defines at least one side wall of the structure. The moulded substrate may comprise a port hole die which defines a port hole through the moulded substrate and an IC die, wherein the port hole die and the IC die are held in fixed positional relationship relative to each other by means of a moulded frame structure. A MEMS microphone transducer may be provided on the upper surface of the moulded substrate. The MEMS microphone transducer may be provided such that the flexible membrane overlies the acoustic port of the moulded substrate.

According to a further aspect there is provided an electronic device comprising a MEMS transducer package according to at least one of the present examples. The device may comprise at least one of: a portable device; a battery powered device; an audio device; a computing device; a communications device; a personal media player; a headphone, a mobile telephone; a games device; and a voice controlled device.

The present aspects and examples seek to provide interposer members or structures which are particularly suitable for batch processing techniques.

### BRIEF DESCRIPTION OF THE DRAWINGS

For a better understanding of the present invention and to show how the same may be carried into effect, reference will now be made by way of example to the accompany drawings in which:

FIGS. 1a and 1b show a schematic diagram and a perspective view, respectively, of a known capacitive MEMS microphone device;

FIG. 2 illustrates a known 3-piece package configuration;

FIG. 3 illustrates an interposer member according to a first present example;

FIG. 4 illustrates an interposer member formed on a carrier sheet according to a further present example;

FIG. 5 illustrates a lid structure for a transducer package according to a further present example;

FIGS. 6a and 6b respectively illustrate a top plan view and a sectional view respectively of a lid structure according to a further present example;

FIGS. 7a and 7b illustrate a MEMS transducer package according to a present example;

FIG. 8 illustrates a composite substrate comprising a moulded main substrate portion;

FIG. 9 shows a cross-sectional view of the composite substrate illustrated in FIG. 8 and a MEMS transducer;

FIG. 10 illustrates a MEMS transducer package according to a present example; and

FIG. 11 illustrates a moulded structure according to a further present arrangement.

### DETAILED DESCRIPTION

The description below sets forth examples and arrangements according to this disclosure. Further examples, arrangements and implementations will be apparent to those having ordinary skill in the art. Further, those having ordinary skill in the art will recognize that various equivalent techniques may be applied in lieu of, or in conjunction with, the examples discussed below, and all such equivalents should be deemed as being encompassed by the present disclosure.

The methods and products described herein can be implemented in a wide range of devices and systems including headphones, audio players, laptops, mobile phones, PDAs, hands-free sets, voice activated or voice-controlled devices and personal computers.

Throughout this description any features which are the same or similar to features in other figures have been given the same reference numerals.

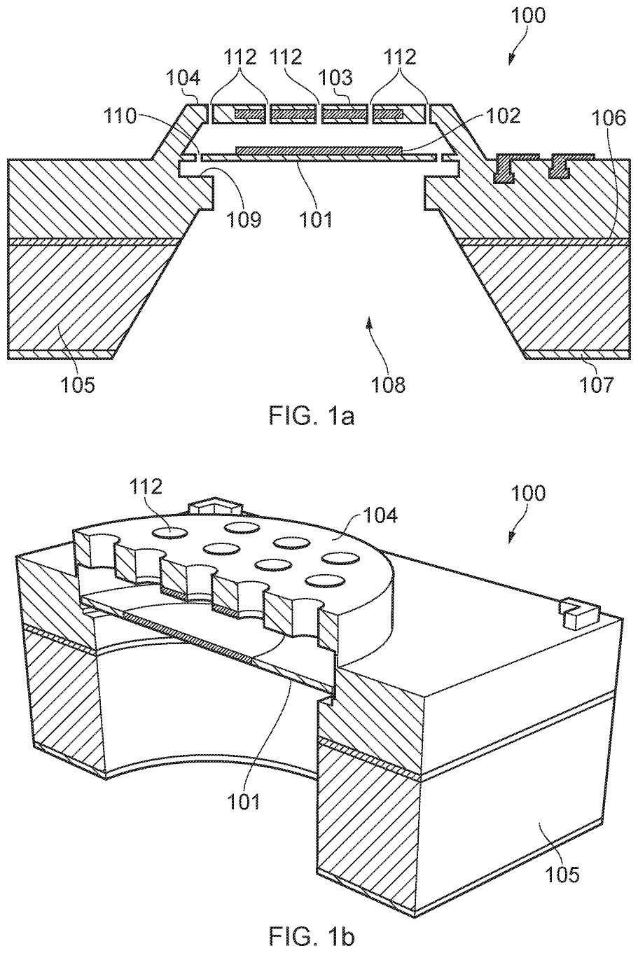

FIGS. 1a and 1b show a schematic diagram and a perspective view, respectively, of a known capacitive MEMS microphone device 100. The capacitive microphone device 100 comprises a membrane layer 101 which forms a flexible membrane which is free to move in response to pressure differences generated by sound waves. A first electrode 102 is mechanically coupled to the flexible membrane, and together they form a first capacitive plate of the capacitive microphone device. A second electrode 103 is mechanically coupled to a generally rigid structural layer or back-plate 104, which together form a second capacitive plate of the capacitive microphone device. In the example shown in Figure la the second electrode 103 is embedded within the back-plate structure 104.

The capacitive microphone is formed on a substrate 105, for example a silicon wafer which may have upper and lower oxide layers 106, 107 formed thereon. A cavity 108 in the substrate and in any overlying layers (hereinafter referred to as a substrate cavity) is provided below the membrane, and may be formed using a “back-etch” through the substrate 105. The substrate cavity 108 connects to a first cavity 109 located directly below the membrane. These cavities 108 and 109 may collectively provide an acoustic volume thus allowing movement of the membrane in response to an acoustic stimulus. Interposed between the first and second electrodes 102 and 103 is a second cavity 110. A plurality of holes, hereinafter referred to as bleed holes 111, connect the first cavity 109 and the second cavity 110.

A plurality of acoustic holes 112 are arranged in the back-plate 104 so as to allow free movement of air molecules through the back plate, such that the second cavity 10 forms part of an acoustic volume with a space on the other side of the back-plate. The membrane 101 is thus supported between two volumes, one volume comprising cavities 109 and substrate cavity 108 and another volume comprising cavity 110 and any space above the back-plate. These volumes are sized such that the membrane can move in response to the sound waves entering via one of these volumes. Typically the volume through which incident sound waves reach the membrane is termed the “front volume” with the other volume, which may be substantially sealed, being referred to as a “back volume”.

In some applications the backplate may be arranged in the front volume, so that incident sound reaches the membrane via the acoustic holes 112 in the backplate 104. In such a case the substrate cavity 108 may be sized to provide at least a significant part of a suitable back-volume. In other applications, the microphone may be arranged so that sound may be received via the substrate cavity 108 in use, i.e. the substrate cavity forms part of an acoustic channel to the membrane and part of the front volume. In such applications the backplate 4 forms part of the back-volume which is typically enclosed by some other structure, such as a suitable package.

It should also be noted that whilst FIGS. 1a and 1b shows the backplate being supported on the opposite side of the membrane to the substrate, arrangements are known where the backplate is formed closest to the substrate with the membrane layer supported above it.

In use, in response to a sound wave corresponding to a pressure wave incident on the microphone, the membrane is deformed slightly from its equilibrium or quiescent position. The distance between the membrane electrode 102 and the backplate electrode 103 is correspondingly altered, giving rise to a change in capacitance between the two electrodes that is subsequently detected by electronic circuitry (not shown).

The membrane layer and thus the flexible membrane of a MEMS transducer generally comprises a thin layer of a dielectric material—such as a layer of crystalline or polycrystalline material. The membrane layer may, in practice, be formed by several layers of material which are deposited in successive steps. Thus, the flexible membrane 101 may, for example, be formed from silicon nitride Si₃N₄ or polysilicon. Crystalline and polycrystalline materials have high strength and low plastic deformation, both of which are highly desirable in the construction of a membrane. The membrane electrode 102 of a MEMS transducer is typically a thin layer of metal, e.g. aluminium, which is typically located in the centre of the flexible membrane 101, i.e. that part of the membrane which displaces the most. It will be appreciated by those skilled in the art that the membrane electrode may be formed by depositing a metal alloy such as aluminium-silicon for example. The membrane electrode may typically cover, for example, around 40% of area of the membrane, usually in the central region of the membrane.

Thus, known transducer membrane structures are composed of two layers of different material—typically a dielectric layer (e.g. SiN) and a conductive layer (e.g. AlSi).

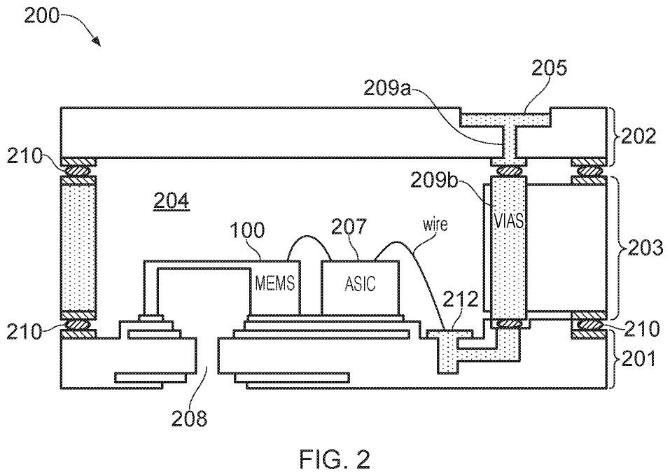

The MEMS transducer will typically be housed within a package. FIG. 2 illustrates a package type known as a three-piece, or “laminate-to-laminate”, package 200. The package shown in FIG. 2 comprises a first, supporting, member 201 and a second, cover, member 202 disposed in a plane overlying the first member 201. The first member 201 may be provided by a PCB substrate, which may for example comprise an FR-4 board core and may further comprise a solder mask stop layer applied to the upper and lower surfaces thereof. The second member 202 may also comprise a PCB and will further comprise one or more contacts 205 provided on an upper (outer) surface thereof. In some arrangements the second cover member 202 may comprise a land grid array (LGA) comprising a plurality of contacts electrically connected to a PCB substrate.

A third member or element 203 (or “interposer member/element”) is interposed between the first 201 and second members 202. The interposer member 203 forms at least a part of the side walls of the package 200. The interposer member 203 can be considered to comprise a cavity or void such that, when the three members are mechanically and electrically bonded together e.g. by means of solder bonds 210, a space or chamber 204 is formed between the lower surface of the second member 202 and an upper surface of the first member 201, wherein the side walls of the chamber 204 are partially provided by the cavity edges of the third member 203. A transducer 101 and an integrated circuit 207 are provided within the chamber 204.

Although several different arrangements are known, according to the FIG. 2 arrangement an acoustic port hole 208 extends through the first member 201 of the package 200 and at least one external electrical connection 205, which may for example comprise solder pads or the like, is provided on the outer surface of the second member 202. According to convention, the configuration shown in FIG. 2—in which the sound port is provided on opposite side of the package to the external electrical connection—is known as a “top port” configuration. It will be appreciated that the term “top port” does not imply any particular orientation of the package device either during manufacture, processing or any subsequent application. In this example, the acoustic port 208 is provided by means of a hole through the first member 201 which, according to the orientation of the package shown in FIG. 2, is illustrated as being beneath the second member.

As shown in FIG. 2, the transducer 100 is supported in a fixed relationship with respect to the first supporting member 201 and is arranged such that the flexible membrane 101 of the transducer extends over—or overlies—the acoustic port 208. The transducer 100 is electrically connected to an integrated circuit 207 which is also supported by the first member 201. It will be appreciated that in order for an electrical signal generated by the transducer, and subsequently by the integrated circuit, to be output from the package, an electrically conductive path must be provided from the transducer to the integrated circuit 207, which is mounted on an inner surface of the first member, and from the integrated circuit to the external electrical connection 205, which is provided on an outer surface of the second member 202. As shown in FIG. 2, this is achieved by means of bond wires, PBC traces and a plurality of conductive vias (vertical interconnected access) 209a and 209b which are provided through the first, second and third members. The bondwires, PCB traces and through vias allow an electrical connection to be made from the lower plane of the integrated circuit up to the upper plane of the external electrical connection 205. Furthermore, a conductive path is also provided between the integrated circuit 207 to an electrical contact 212 on the upper surface of the first member and to the bottom of the via 209b.

According to the arrangement shown in FIG. 2, the interposer member 203, which may typically comprise a PCB, comprises a cavity or void which will ultimately define the chamber of the assembled package. The void is usually formed by a processes of milling or punching the PCB or substrate portion to remove the substrate material. The interposer member 203 will also need to be further processed to form at least one vertical channel, or through hole, which will be subsequently metal plated to form an electrically conductive through via. It will be appreciated that a relatively high cost may be associated with the process of forming the void and/or the vertical channel(s). Typically the size of a tool for removing material from a PCB relative to the size of the interposer element means that a series of milling processes needs to be conducted to process an entire PCB wafer comprising a plurality of interposer members. Furthermore, the process of removing the PCB material from the interposer member to create the void and/or the channels, may suffer from poor tolerances resulting in an undesirable degree of dimensional variation. This may result in a degradation in the acoustic and/or electrical performance of the device.

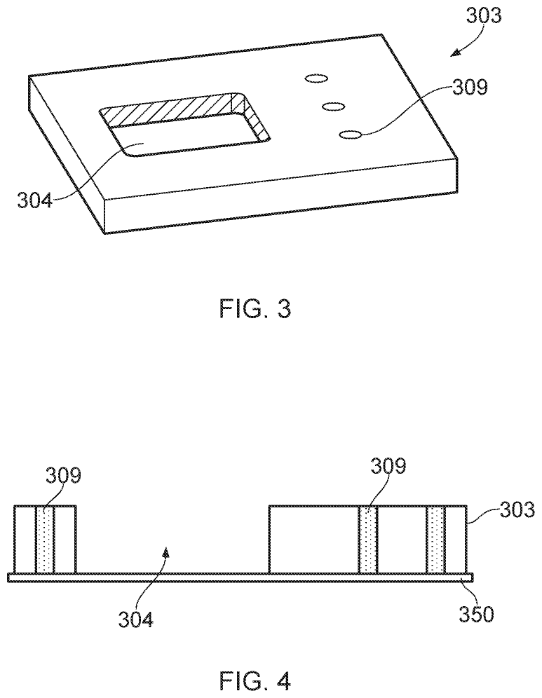

FIG. 3 illustrates an interposer member 303 according to a present example. The interposer member 303 comprises a void 304 which extends from an opening in an upper surface of the interposer member to an opening in a lower surface of the interposer member 303. The interposer member 303 also comprises a plurality of electrically conductive through vias 309. The through vias 309 each comprise a vertical channel or through hole which is plated with an electrically conductive material. The vias 309 extend through the plane of the interposer member 303 in order to allow an electrical connection to be formed between the lower surface of the interposer member and the upper surface of the interposer member.

According to the present arrangement the interposer member 303 is formed of a mould material. The mould material is preferably a hardenable or settable material which may be dispensed or applied in liquid form and manipulated to define the required shape, dimensions and features of the interposer member. For example, the mould material may be an epoxy mould material, a polymer or a polymeric material. The mould material may be considered to be an electrically insulating mould material.

FIG. 4 illustrates an interposer member 303 formed on a carrier sheet 350. During a process of fabricating the interposer layer 303, the carrier sheet 350 may be used to support the liquid moulding material as the interposer layer is formed by a moulding technique. For example, a moulding tool (not shown) may be positioned relative to the carrier sheet 350 to define the boundary of the intended interposer member. Thus, a moulding tool is applied relative to the carrier sheet 350 and serves to delimit a region where the moulding substance is not desired, thus leaving a vacant region where the moulding material is desired. In particular, the moulding tool defines a generally planar member and also delimits the void region of the interposer member. The moulding tool may also define a plurality of intra-planar channels which, once plated, will form vias 309 for facilitating an electrical path through the interposer member. A moulding substance is applied to the interior vacant region defined by the moulding tool. The moulding substance is preferably a settable material which may be applied in fluid form and the allowed to harden or set in order to form a solid, moulded interposer layer 303. The setting of the moulding substance may be achieved or accelerated by a process of curing for example. Once the moulding substance has hardened the carrier sheet may be removed to result in the solid interposer member 303. For ease of illustration FIG. 4 shows the fabrication of a single interposer member. However, it will be appreciated that a plurality or batch of interposer members will advantageously be formed as part of a single process.

An interposer member 303 as illustrated in FIG. 3 or FIG. 4 may be utilised as a component layer or element of a MEMS transducer package. In particular, an interposer member 303 as illustrated in FIG. 3 or 4 may be utilised as a member or portion that is provided between a cover member and a substrate member of a package, wherein the void 304 of the interposer member 303 will define an inner chamber or cavity of the package. Thus, the interposer member 303 may be attached to upper and/or lower members, e.g. by a soldering process, in order to define a package.

Preferably the plurality of vias may be located having regard for the intended position(s) of one or more contact points in the plane beneath and/or above the interposer member. In the FIG. 3 arrangement the interposer member 303 comprises three vias which are intended to facilitate an electrical connection from circuitry of the intended MEMS transducer package. The three vias can be considered to correspond to three contact points for power, signal and ground. In other arrangements a plurality of vias may be arranged at intervals to define a notional ring around the chamber or void of the interposer member. The vias forming part of the notional ring may typically be connected to ground.

There are a number of advantages associated with the provision of a moulded interposer member. In particular, it will be appreciated that using a moulding tool to define the vacant regions of the interposer member—in particular the void for the package chamber and the through holes or via channels—potentially offers improved tolerances as compared with the process of removing material by milling. Furthermore, the process of forming a moulding interposer member is highly repeatable and readily applicable to batch processing, improving the efficiency and effectiveness of the manufacturing process. In circumstances where the void of the interposer member defines a back chamber for a MEMS microphone device, the improved dimensional accuracy achieved in the formation of the void may also enhance the acoustic performance of the MEMS microphone device.

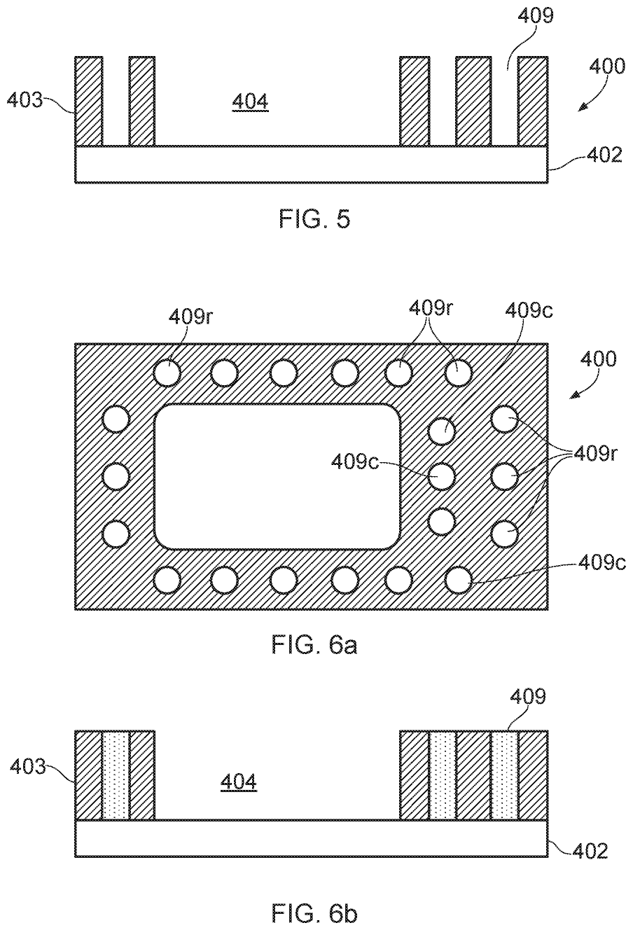

FIG. 5 shows a lid 400 for a transducer package according to a further example. The lid comprises an interposer member 403 and a cover 402. The interposer member 403 forms the side walls of the lid structure 400. The process of fabricating the lid structure is similar to the method described with respect to FIG. 4, except that the interposer member 303 is moulded directly onto the cover 402. As the moulding material sets or hardens, a rigid bond or attachment is formed between the moulding material and the underlying substrate 402. Following removal of the moulding tool(s) the interposer member will comprise a void 404 and a plurality of through holes 409. In a subsequent step as illustrated in FIGS. 6a and 6b—which illustrate a top plan view and a sectional view respectively of the lid 400—the through holes 409 are plated with a conductive metal to define a plurality of vias. In this example, a first sub-group of the vias 409c may be considered to define an intended inter-planar connection for power, signal and ground. A second sub-group of vias 409r can be considered to be spaced along a notional path that defines a ring or closed shape that surrounds the void 404 and which is defined at or near the perimeter of the interposer member. It will be appreciated that the substrate 402 may provide a cover member of the lid and that the lid may be provided in conjunction with another substrate member to define a package or enclosure, wherein the interposer member 403 defines the side walls of the package. The cover member may comprise at least one via (not shown) which extends through the plane of the cover member. The, or each via may provide an intra-planar connection between at least one via 409 of the interposer member and an external electrical connection of the cover member.

In addition to the advantages discussed above in relation to the formation of the moulded interposer member, the arrangement shown in FIGS. 5 and 6 also obviates the need for a soldering layer between the cover portion and the interposer portion of a package.

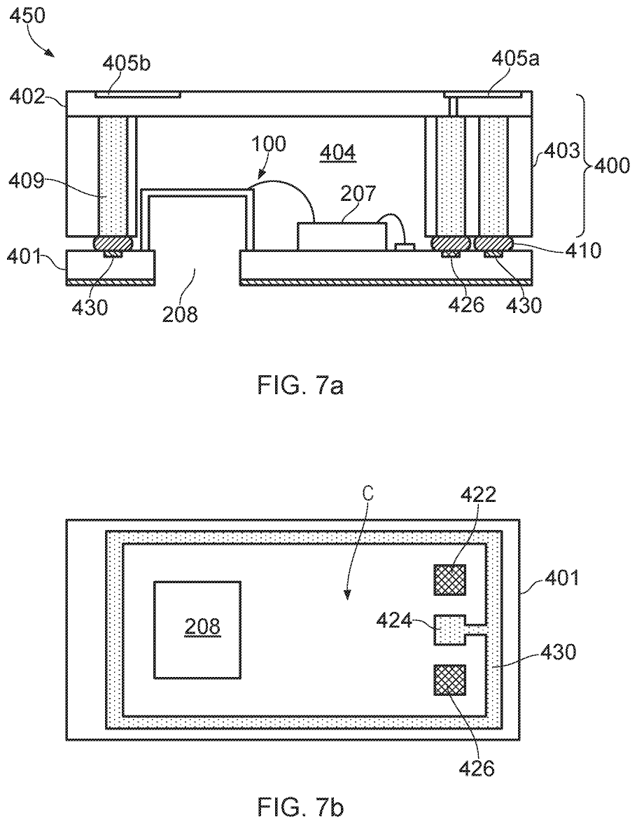

FIG. 7a illustrates a MEMS transducer package 450 comprising a first member 401 and a lid 400, which may be similar to the lid illustrated in FIG. 6. Thus, as shown in FIG. 7a the lid comprises an interposer member 403 and a first planar member or substrate 402, wherein the lid 400 is attached to the upper surface of the substrate 401 by means of at least one solder bond 410. Thus, the package 450 is formed with only a single soldering layer.

The interposer member 403 comprises a void 404, the inner surfaces of which define an interior chamber of the package in conjunction with the inner surface of the cover portion 402 of the lid and the first member 401. The interposer member 403 also comprises a plurality of metal-plated vias 409 which extend through the plane of the interposer member 403. The vias are arranged having regard for the intended position(s) of one or more contact points provided in the substrate plane beneath the interposer member where the circuitry will be mounted. FIG. 7b illustrates a top plan view of the first member 401 which forms a supporting substrate of the package. The supporting substrate 401 comprises an acoustic port 208 over which the flexible membrane of the MEMS microphone transducer is intended to be disposed. The supporting substrate also comprises a circuitry region C where an integrated circuit is intended to be mounted and three electrically conductive contact points 422, 424 and 426. The contact points facilitate an electrical connection for power, output signal and ground between the IC/transducer and the rest of the package elements. As illustrated in FIG. 7b, the ground contact 424 is connected to an electrically conductive ring 430 which extends near a perimeter region of the substrate 401. Referring again to the lid structure illustrated in FIG. 6, it will be appreciated that when the lid structure is mounted on the supporting substrate 401 there will be a positional correspondence between the contact points 422, 424 and 426 and the vias 409c. It will also be appreciated that when the lid structure is mounted on the first member 401 there will be a positional correspondence between the notational ring of vias 409r and the ground ring 430 provided on the upper surface of the first member 401.

In United Kingdom patent application No. 1905930.2 filed by the present Applicant there is described a substrate suitable for a MEMS transducer package. The entire contents of this earlier application is incorporated herein by way of reference thereto.

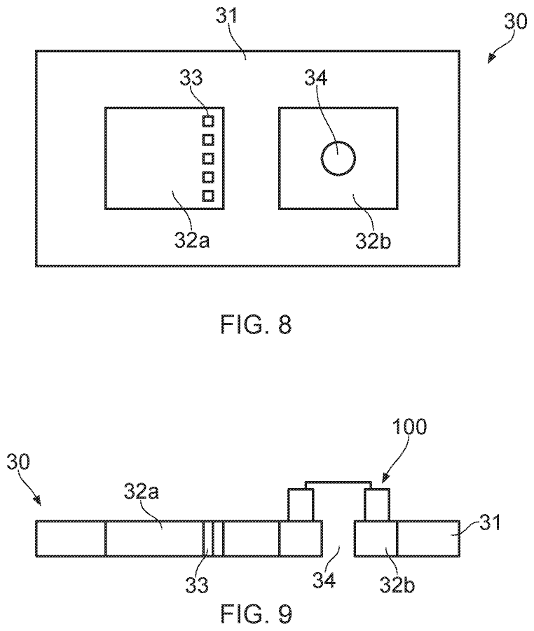

FIG. 8 shows a substrate that is described in the earlier, incorporated application. The substrate 30 comprises an IC die 32a and a port-hole die 32b. The IC die 32a and the port-hole die 32b are held in a fixed positional arrangement by means of a moulded frame structure 31. The frame structure 31 laterally surrounds both the IC die 32a and the port hole die 32b and defines the overall plane of the substrate 30. The port-hole die is a die of semiconductor material having a hole 34 which extends through the die from an opening in an upper surface of the die 32b to an opening in a lower surface thereof. The IC die may optionally comprise a plurality of through silicon vias (TSV) 33. As will be known by those skilled in the art a TSV is a vertical electrical connection that passes completely through the die and may be used, in conjunction with an associated bond pad, as an electrical interconnect to facilitate connection to an adjacent level or plane of interconnect within and without a package structure. Thus, a TSV facilitates an electrical connection to be formed through the plane of the IC die in order to form connections between a region above the upper surface of the IC die and a region below the surface of the IC die. In an alternative embodiment a through planar via is formed through the moulded frame and may be considered to be a through mould via or TMV. Furthermore, at least one redistribution layer or RDL (not shown) may be formed on the upper and/or lower surface of the substrate 30. As will be understood by those skilled in the art an RDL is a metal, e.g. copper, layer which serves to redistribute or relocate electrical connections.

The substrate illustrated in FIG. 8 may be considered to comprise a composite substrate comprising one or more intra-planar die provided in a region between a first plane defined by the upper surface of the composite substrate and a second plane defined by the lower surface of the composite substrate. The FIG. 8 substrate may be particularly useful in supporting a MEMS transducer since the hole 34 of the port-hole die allows the passage of acoustic pressure waves to a region directly above the upper surface of the substrate. This is illustrated in FIG. 9 which shows a cross-sectional view of a substrate 30 similar to the substrate illustrated in FIG. 8 and further comprising a discrete MEMS transducer die 100 provided in a region above the port-hole die. The MEMs transducer die may comprise a MEMS microphone transducer. The substrate 30 can be considered to be a composite structure comprising a planar, rigid frame and first and second die formed within the plane of the frame.

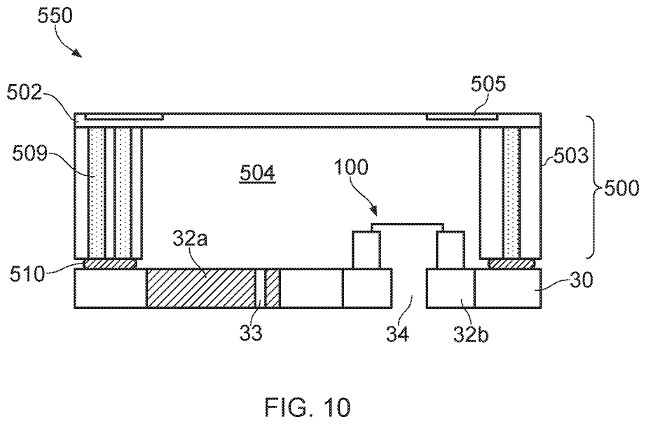

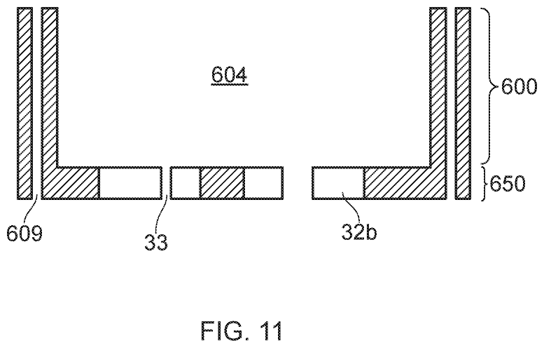

FIG. 10 illustrates a MEMS transducer package 550 according to a present example comprising a first planar member or substrate 30, which may be similar to the substrate illustrated in FIG. 9, and a lid 500. The lid 500 comprises a moulded interposer member 503 which is bonded to a cover portion 502. The cover portion may comprise e.g. a PCB. The lid 500 is attached to the upper surface of the substrate 30 by means of at least one solder bond 510. Thus, the package 550 is beneficially formed with only a single soldering layer.

The interposer member 503 comprises a void 504, the inner surfaces of which define an interior chamber of the package in conjunction with the inner surface of the cover portion 502 of the lid and the substrate. The interposer member 503 also comprises a plurality of metal-plated vias 509 which extend through the plane of the interposer member 503 to facilitate an intraplanar connection between the integrated circuit 32a and at least one external contact 505.

According to a further arrangement, and as shown in FIG. 11, an interposer member 600 is formed directly onto, or integrally with, a moulded substrate 650, which may be similar to the substrate illustrated in FIG. 9. Thus, according to one or more arrangements there is provided a moulded structure comprising a substrate portion and a side wall portion. The moulded structure may be conveniently formed by a moulding process applied onto a carrier sheet. Thus, an IC die 32a and a port-hole die 32b may be mounted by side on a carrier. Each pair of IC die 32a and port-hole die 32b will form part of a composite substrate of the moulded structure. The carrier tape beneficially supports a plurality of die pairs and allows the fabrication of an assembly of moulded structures. A moulded substrate frame is formed in the region laterally surrounding the IC and port hole die by a process of film assisted moulding. Specifically, moulding material is applied to the region laterally surrounding the two die e.g. using a film or tool which defines one or more of the boundary surfaces of the intended substrate assembly. The moulding material may comprise e.g. a polymer or epoxy type material. The moulding material is preferably a hardenable or settable material which may be applied in liquid form and which, when hardened, serves to generate a rigid substrate structure. Thus, the ASIC die and the port-hole die are ultimately provided within the plane of the substrate and with a fixed positional relationship between them. The moulding process also delineates moulded side walls which can be considered to define an interposer portion 600 of the structure. The side walls comprise a plurality of through holes 609 which are formed through the mould material and are defined as part of the moulding process e.g. by a moulding tool. A void region 604 defined by the moulding process (e.g. by a moulding tool which occupies the region 604 when the mould material is applied and which also protects the TSV 33 of the ASIC die and the port hole of the port hole die) will form an interior chamber of a MEMS transducer package, e.g. in conjunction with a cover portion (not shown). A MEMS transducer may be mounted relative to the port hole of the port hole die 32b.

Once the carrier sheet is removed following the hardening of the mould material a metal ground layer, or an RDL, may be applied to the underside of the substrate. Alternatively, the moulded structure may be formed onto a lead frame.

It will be appreciated that a plurality of interposer members may be fabricated as a batch, taking advantage of moulding techniques which facilitate the defining of the void and through holes and which are readily suitable for batch processing. This is in contrast to previously proposed methods which typically involved needing to remove material from an interposer member (or wafer portion defining an interposer member) one at a time.

It is noted that the example embodiments described above may be used in a range of devices, including, but not limited to: analogue microphones, digital microphones, pressure sensor or ultrasonic transducers. The example arrangements may also be used in a number of applications, including, but not limited to, consumer applications, medical applications, industrial applications and automotive applications. For example, typical consumer applications include portable audio players, laptops, mobile phones, PDAs and personal computers. Example arrangements may also be used in voice activated or voice controlled devices. Typical medical applications include hearing aids. Typical industrial applications include active noise cancellation. Typical automotive applications include hands-free sets, acoustic crash sensors and active noise cancellation.

Features of any given aspect or example may be combined with the features of any other aspect or example and the various features described herein may be implemented in any combination in a given arrangement.

Associated methods of fabricating an interposer member, a lid structure and a MEMS transducer package are respectively provided.

It should be understood that the various relative terms above, below, upper, lower, top, bottom, underside, overlying, underlying, beneath, etc. that are used in the present description should not be in any way construed as limiting to any particular orientation of the transducer during any fabrication step and/or it orientation in any package, or indeed the orientation of the package in any apparatus. Thus the relative terms shall be construed accordingly.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference signs in the claims shall not be construed so as to limit their scope.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

1. An interposer member for a MEMS package, wherein the interposer member is formed of a mould material and comprises:
a void which extends through the interposer member from an upper surface to a lower surface of the interposer member;
one or more through holes which extend between the upper surface of the interposer member and the lower surface of the interposer member.

2. An interposer member as claimed in claim 1 wherein the one or more through holes comprise with an electrically conductive material.

3. An interposer member as claimed in claim 1, comprising a plurality of through holes, wherein at least some of the through holes are spaced on a notional path which surrounds the void.

4. A lid structure for a MEMS package, the lid comprising an interposer member as claimed in any preceding claim formed in connection with a first surface of a cover member, wherein the interposer member defines at least one side wall of the lid structure.

5. A lid structure for a MEMS package as claimed in claim 4, wherein the cover member comprises at least one electrical contact formed on a second surface of the cover member, the second surface being opposite to the first surface.

6. A lid structure as claimed in claim 5, wherein the cover member comprises at least one via which extends through the plane of the cover member between the first surface and the second surface thereof.

7. A MEMS package comprising a lid structure as claimed in claim 4, further comprising a package substrate.

8. A MEMS package as claimed in claim 7, wherein the lid structure is attached to a first (upper) surface of the package substrate by one or more solder bonds.

9. A MEMS package as claimed in claim 8, wherein the package substrate comprises at least one electrical contact formed on an upper surface thereof, wherein a through hole of the interposer member corresponds to each electrical contact and is provided so as to at least partially overlie the corresponding electrical contact.

10. A MEMS package as claimed in claim 8, wherein a ring of conductive material is formed on an upper surface of the package substrate, the ring of conductive material underlying at least some of the plurality of through holes of the interposer member.

11. A MEMS package as claimed in claim 8, wherein the package substrate comprises a cavity which extends through the plane of the package substrate and defines an acoustic port of the package.

12. A MEMS package as claimed in claim 11, further comprising a MEMS microphone transducer provided on the upper surface of the package substrate.

13. A MEMS package as claimed in claim 12, wherein the MEMS microphone transducer comprises a flexible membrane which deflects in response to a pressure differential across the membrane, and wherein the MEMS microphone transducer is provided such that the flexible membrane overlies the acoustic port of the package.

14. A MEMS package as claimed in claim 11, further comprising an IC die mounted to the upper surface of the package substrate.

15. A MEMS package as claimed in claim 8, wherein the package substrate comprises a moulded substrate.

16. A MEMS package as claimed in claim 15, wherein the moulded substrate comprises a port hole die which defines an acoustic port of the package and an IC die, wherein the port hole die and the IC die are held in fixed positional relationship relative to each other by means of a moulded frame structure.

17. A MEMS package as claimed in claim 16, further comprising a MEMS microphone transducer provided on the upper surface of the package substrate.

18. A MEMS package as claimed in claim 17, wherein the MEMS microphone transducer comprises a flexible membrane which deflects in response to a pressure differential across the membrane, and wherein the MEMS microphone transducer is provided such that the flexible membrane overlies the acoustic port of the package.

19. A substrate structure for a MEMS transducer package comprising an interposer member as claimed in claim 1 and a moulded substrate, wherein the interposer member is mounted on or formed integrally with the moulded substrate and wherein the interposer member defines at least one side wall of the structure.

20. A substrate structure as claimed in claim 19, wherein the moulded substrate comprises a port hole die which defines a port hole through the moulded substrate and an IC die, wherein the port hole die and the IC die are held in fixed positional relationship relative to each other by means of a moulded frame structure.

21. A substrate structure as claimed in claim 20, further comprising a MEMS microphone transducer provided on the upper surface of the moulded substrate.

22. A substrate structure as claimed in claim 21, wherein the MEMS microphone transducer comprises a flexible membrane which deflects in response to a pressure differential across the membrane, and wherein the MEMS microphone transducer is provided such that the flexible membrane overlies the acoustic port of the moulded substrate.

23. An electronic device comprising a MEMS transducer package as claimed in claim 7 wherein the device is at least one of: a portable device; a battery powered device; an audio device; a computing device; a communications device; a personal media player; a headphone, a mobile telephone; a games device; and a voice controlled device.

24. (canceled)
